(19) United States
(12) Patent Application Publication
(10) Pub. No.: US 2004/0057330 A1
(43) Pub. Date: Mar. 25, 2004

(54) Circuit topology for clock signal distribution topology

(76) Inventor: Chung-Hsiao R. Wu, Sunnyvale, CA (US)

Correspondence Address: B. Noel Kivlin, Conley, Rose, & Tayon, P.C., P.O. Box 398, Austin, TX, 78767, US

(21) Appl. No.: 10/247,425

(22) Filed: Sep. 19, 2002

(51) Int. Cl. G11C 8/00

(52) U.S. Cl. 365/233

(57) ABSTRACT

A method and apparatus for providing a differential clock signal to a plurality of memory modules. In one embodiment, an electronic circuit (e.g. computer system motherboard) includes a clock generating circuit and one or more memory modules. The memory modules may be coupled to receive a differential clock signal from the clock generating circuit via a pair of transmission lines. Each transmission line may be coupled to one of the differential clock inputs on the memory module by a series-connected resistor. Since the differential clock inputs for each memory module are coupled to the transmission lines by series-connected resistors, the changing of the memory module population may have a minimal effect on capacitive loading, and thus delays, than on memory modules where the differential clock inputs are terminated by parallel-connected resistors.

### BACKGROUND OF THE INVENTION

1. Field of the Invention

This invention relates to computer systems, and more particularly circuitry to support the distribution of clock signals.

2. Description of the Related Art

The demand for increased computing power in computer systems is ever increasing. Such demands include the demand for faster processors, additional memory, and faster system boards. The demand for faster processors and system boards often times results in the need for faster clock speeds.

As clock speeds increase, the effects of loading may become more significant in the distribution of clock signals. FIG. 1 illustrates a typical circuit topology for clock distribution. In the embodiment shown, a memory controller having a phase-locked loop (10) distributes the differential clock signal to DIMM (dual inline memory module) 20 via a point-to-point connection. Additional memory modules may be coupled to the MC/PLL in the same manner using separate pairs of transmission lines. Each DIMM 20 may include a resistor that is electrically coupled between the transmission lines. Thus, for each DIMM slot on the board, a separate pair of transmission lines may be required. One possible solution to this problem is to use the same pair of transmission lines for each of the DIMMs. However, if a single pair of transmission lines were used, the resistance between each transmission line of the pair would vary with the DIMM population due to the parallel connection of the termination resistors, and hence the loading might also vary. Such a configuration could potentially lead to timing mismatches and possibly limit the maximum clock speed at which the system board upon which the DIMMs are implemented may operate.

### SUMMARY OF THE INVENTION

A method and apparatus for providing a differential clock signal to a plurality of memory modules is disclosed. In one embodiment, an electronic circuit (e.g. computer system motherboard) includes a clock generating circuit and one or more memory modules. The memory modules may be coupled to receive a differential clock signal from the clock generating circuit via a pair of transmission lines. Each transmission line may be coupled to one of the differential clock inputs on the memory module by a series-connected resistor. Since the differential clock inputs for each memory module are coupled to the transmission lines by series-connected resistors, the changing of the memory module population may have a minimal effect on resistive loading, and thus delays, than on memory modules where the differential clock inputs are terminated by parallel-connected resistors.

### BRIEF DESCRIPTION OF THE DRAWINGS

Other aspects of the invention will become apparent upon reading the following detailed description and upon reference to the accompanying drawings in which:

FIG. 1 (Prior Art) is a diagram illustrating one embodiment of the distribution of a differential clock signal to a memory module, the distribution network employing parallel termination;

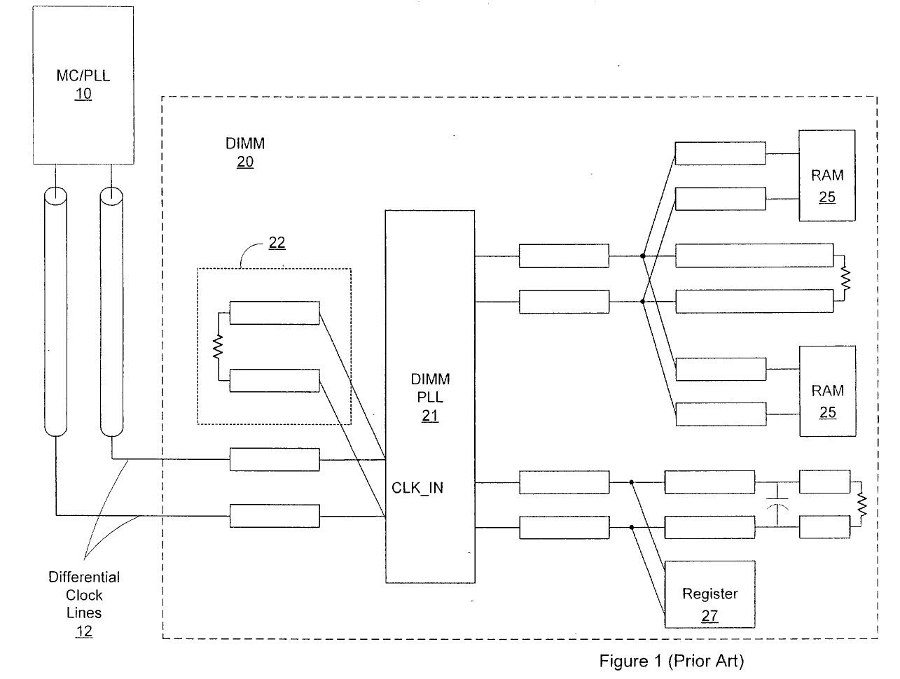

FIG. 2A is a diagram illustrating one embodiment of the distribution of a differential clock signal to a memory module, the distribution network employing resistors connected in series to a differential clock input pair;

FIG. 2B is a diagram illustrating an alternate embodiment of the clock distribution network; and

FIG. 3 is a diagram illustrating one embodiment of the distribution of a differential clock signal to a plurality of memory modules.

While the invention is susceptible to various modifications and alternative forms, specific embodiments thereof are shown by way of example in the drawings and will herein be described in detail. It should be understood, however, that the drawings and description thereto are not intended to limit the invention to the particular form disclosed, but, on the contrary, the invention is to cover all modifications, equivalents, and alternatives falling with the spirit and scope of the present invention as defined by the appended claims.

### DETAILED DESCRIPTION OF THE INVENTION

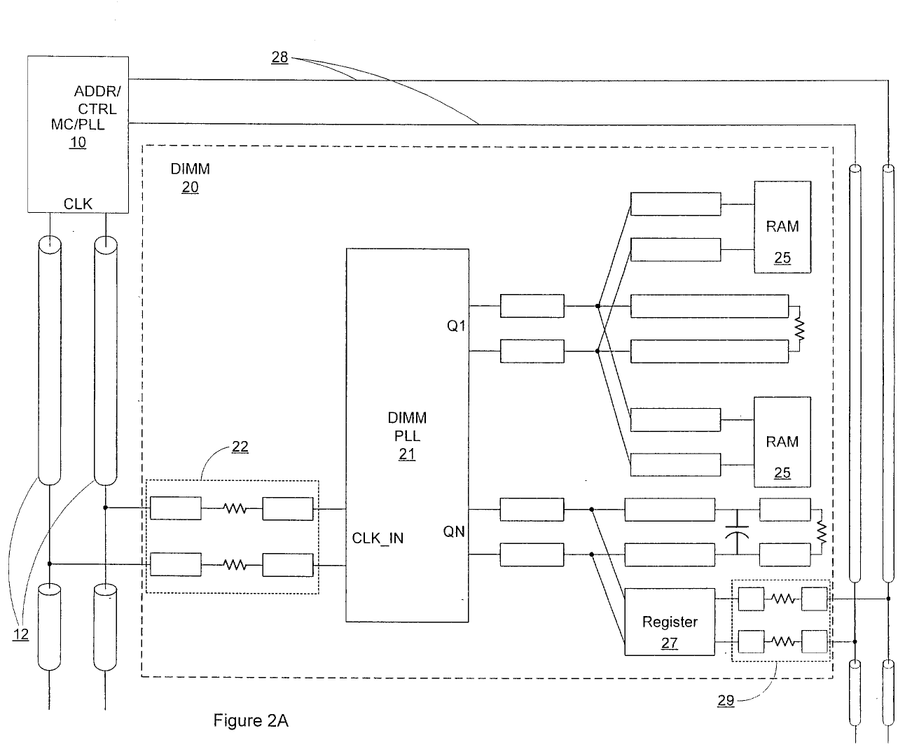

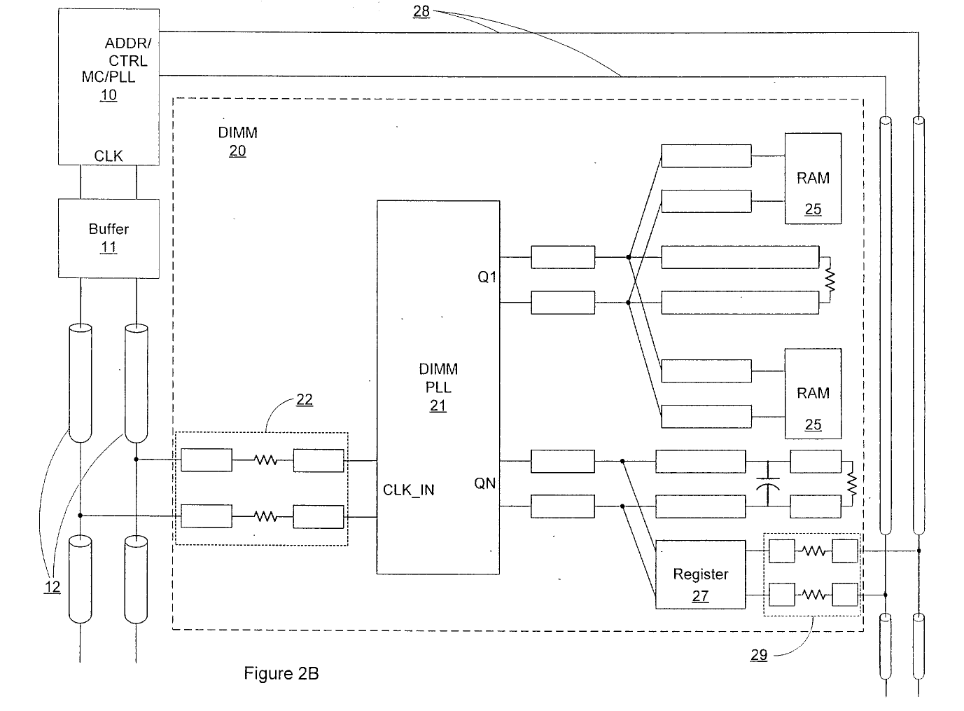

Turning now to FIG. 2A, a diagram illustrating one embodiment of the distribution of a differential clock signal to a memory module is shown, wherein the distribution network includes resistors connected in series to a differential clock input pair. In the embodiment shown, memory controller/phase locked loop (MC/PLL) 10 includes a differential clock output to differential clock lines 12. Other embodiments are possible and contemplated wherein the PLL (or other clock generating circuit) is separate from the memory controller. MC/PLL 10 also includes address and control signal outputs which are coupled to differential signal lines 28. Embodiments are possible and contemplated wherein address and control signals are coupled to single-ended signal lines as well. A plurality of differential signal line pairs may be present in various embodiments, however, a single differential signal line pair is shown here for the sake of simplicity. Differential signal lines 28 may also be configured to connect to additional DIMMs (not shown here), as may be differential clock lines 12.

Dual-inline memory module (DIMM) 20 is coupled to MC/PLL 10 by both differential clocks lines 12 and differential signal lines 28. In the embodiment shown, DIMM 20 includes DIMM PLL 21, which has a differential clock input (CLK_IN). DIMM PLL 21 may include a plurality of differential clock outputs, represented here as Q1 and QN. Any number of differential clock outputs may be present. In the example shown here, the differential clock output may be conveyed through transmission lines to a pair of random access memory (RAM) chips 25 from Q1, and to a register 27 from QN. Additional RAM chips 25 and/or registers 27 may be present on DIMM 20.

Differential clock lines 12 and differential signal lines 28 may both be electrically connected to DIMM 20 by networks 22 and 29. More particularly, differential clock lines 12 may be coupled to the clock input of DIMM PLL 21 by network 22, while register 27 may be coupled to differential signal lines 28 by network 29. Network 22 includes a pair of resistors and corresponding transmission lines which couple each input of the differential clock input pair to a corresponding differential clock line 12. Similarly, network 29 also includes a pair of resistors and corresponding transmission lines which electrically connect register 27 to differential signal lines 28. Thus, unlike many other clock distribution topologies, the topology shown here matches the address/control signal distribution topology. This may minimize or eliminate delay mismatches between the clock signal and address/command signals, and thus preserve sufficient timing margins. This may be especially important at higher frequencies (e.g. 500 MHz and above) as timing margins at such frequencies are typically smaller than at lower frequencies.

It should be noted that other types of memory modules (e.g. single inline memory modules, or SIMMs) may also employ the clock distribution topology of FIG. 2A. Furthermore, the clock distribution topology may be used where memory chips are mounted directly to a computer system motherboard, and may be used in other types of electronic equipment as well.

In one embodiment, the clock distribution topology may be designed to meet the JEDEC (Joint Electron Device Engineering Council) SSTL_18 standard (stub series terminated logic). In such an embodiment, the transmission lines of differential clock lines 12 and differential signal lines 28 may be 50-ohm transmission lines, while networks 22 and 29 may utilize 60-ohm transmission lines. A nominal supply voltage of 1.8 volts may also be used, with a reference voltage of 0.9 volts. Furthermore, both the transmitters (e.g. CLK output of MC/PLL 10) and receivers (CLK_IN input of DIMM PLL 21) may have the appropriate output/input impedances in order to match those of the transmission lines. Other embodiments may employ design standards different from the JEDEC SSTL_18 standard.

FIG. 2B is a diagram illustrating an alternate embodiment of the clock distribution network. In the embodiment shown, buffer 11 is connected between the CLK output of MC/PLL 10 and differential clock lines 12. Buffer 11 may be coupled to the differential clock signal from the clock output and distribute it to a plurality of DIMMs 20 (or other type of memory module in other embodiments, as well as embodiments having memory chips mounted on a system board). Buffer 11 may provide additional drive strength to the differential clock signal when it is to be distributed to a large number of devices. Buffer 11 may be configured such that its input and output impedances are approximately matched with the transmission lines coupling it to both MC/PLL 10 and the DIMMs 20 or other memory module type in the system. Buffer 11 may be configured for the JEDEC SSTL_18 standard discussed above, or other standard to which the clock distribution topology may conform.

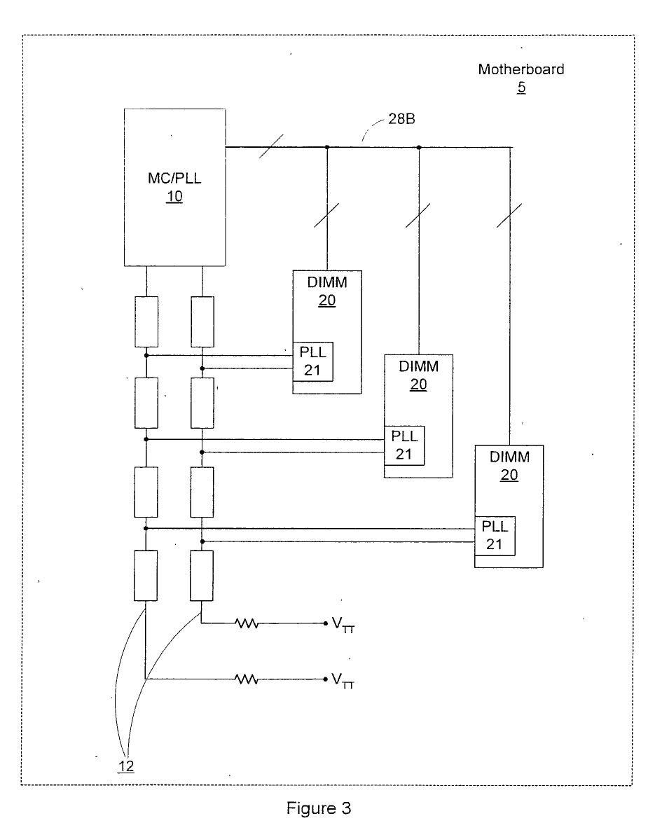

FIG. 3 is a diagram illustrating one embodiment of the distribution of a differential clock signal to a plurality of memory modules. In the embodiment shown, MC/PLL is mounted to motherboard 5, and it coupled to a plurality of DIMMs 20 by differential clock lines 12. Each DIMM 20 includes a PLL 21 which is coupled to receive the differential clock signal. Although not explicitly shown here, each DIMM 20 includes a network 22 as shown in FIGS. 2A and 2B which is coupled to differential clock lines 12 and a differential clock input of the corresponding PLL 21. Each DIMM 20 may also be coupled to MC/PLL 10 by control/address bus 28B, which may be comprised of a plurality of differential signal pairs such as the pair of differential signal lines 28 shown in FIGS. 2A and 2B.

In the embodiment shown, differential clock lines 12 are electrically terminated by two resistors electrically connected to a voltage V_{TT}. In this particular embodiment, the clock topology conforms to the JEDEC SSTL_18 standard, wherein V_{TT} is equal to V_{REF} ±0.04 volts. V_{REF} in this embodiment has a nominal voltage of 0.9 volts. It should be noted that other standards and voltage levels may be used as well, and the JEDEC SSTL_18 standard discussed here is used in only one or many possible embodiments. Other standards may include the JEDEC SSTL_2 standard, which uses a nominal supply voltage of 2.5 volts and a nominal reference voltage of 1.25 volts.

While the present invention has been described with reference to particular embodiments, it will be understood that the embodiments are illustrative and that the invention scope is not so limited. Any variations, modifications, additions, and improvements to the embodiments described are possible. These variations, modifications, additions, and improvements may fall within the scope of the inventions as detailed within the following claims.

What is claimed is:

1. An electronic circuit comprising:
a clock generating circuit configured to generate a differential clock signal;
a pair of transmission lines for conveying the differential clock signal, the transmission lines coupled to the clock generating circuit;
one or more memory modules; and
a plurality of resistor pairs, wherein each of the one or more memory modules is coupled to the transmission lines by one of the resistor pairs, and where each resistor of the one of the resistor pairs is coupled in series between one of the transmission lines and one of the one or more memory modules.

2. The electronic circuit as recited in claim 1, wherein each of the one or more memory modules includes a phase locked loop (PLL), wherein the PLL includes a differential clock input coupled to receive the differential clock signal.

3. The electronic circuit as recited in claim 2, wherein each of the one or more memory modules includes a plurality of RAM (random access memory) chips coupled to receive the differential clock signal from the PLL.

4. The electronic circuit as recited in claim 1, wherein the electronic circuit is a computer system motherboard, and wherein the computer system motherboard includes a memory controller.

5. The electronic circuit as recited in claim 4, wherein the memory controller includes the clock generating circuit.

6. The electronic circuit as recited in claim 4, wherein the computer system motherboard includes a buffer coupled to receive the differential clock signals from the clock generating circuit and drive the clock generating circuit to the one or more memory modules.

7. The electronic circuit as recited in claim 1, wherein each of the one or more memory modules is a dual inline memory module (DIMM).

8. A method for conveying a differential clock signal to a memory module in an electronic circuit having one or more memory modules, the method comprising:
generating a differential clock signal using a clock generation circuit;
conveying the differential clock circuit via a pair of transmission lines;
a memory module receiving the differential clock signal, wherein the memory module includes a differential clock input pair for receiving the differential clock signal, and wherein each input of the differential clock input pair is connected to one of the pair of transmission lines by a series connected resistor.

9. The method as recited in claim 8, wherein the memory module includes a phase locked loop (PLL), wherein the PLL includes the differential clock input pair coupled to receive the differential clock signal.

10. The method as recited in claim 9, wherein the memory module modules includes a plurality of RAM (random access memory) chips coupled to receive the differential clock signal from the PLL.

11. The method as recited in claim 8, wherein the electronic circuit is a computer system motherboard, and wherein the computer system motherboard includes a memory controller.

12. The method as recited in claim 11, wherein the memory controller includes the clock generating circuit.

13. The method as recited in claim 11, wherein the computer system motherboard includes a buffer coupled to receive the differential clock signals from the clock generating circuit and drive the clock generating circuit to the one or more memory modules.

14. The method as recited in claim 8, wherein each of the one or more memory modules is a dual inline memory module (DIMM).

15. A memory module comprising:
a phase locked loop (PLL) circuit having a differential clock input pair;
a first resistor and a second resistor, wherein the first resistor is coupled to connect a first input of the differential clock input pair to a first transmission line of an electronic circuit and wherein the second resistor is coupled to connect a second input of the differential clock input pair to a second transmission line of the electronic circuit, wherein the first and second transmission lines are coupled to a clock generating circuit on a computer system motherboard, wherein the clock generating circuit is configured to generate a differential clock signal.

16. The memory module as recited in claim 15, wherein the memory module further includes a plurality of RAM (random access memory) chips, the RAM chips coupled to receive the differential clock signal from the PLL circuit.
